(19) United States
(12) Patent Application Publication
(10) Pub. No.: US 2010/0032820 A1
(43) Pub. Date: Feb. 11, 2010

(54) Stacked Memory Module

(76) Inventors: Michael Bruennert, Muenchen (DE); Peter Gregorius, Muenchen (DE); Georg Braun, Holzkirchen (DE); Andreas Gaertner, Muenchen (DE); Hermann Ruckerbauer, Moos (DE); George William Alexander, Durham, NC (US); Johannes Stecker, Muenchen (DE)

Correspondence Address: SLATER & MATSIL, L.L.P., 17950 PRESTON ROAD, SUITE 1000, DALLAS, TX, 75252, US

(21) Appl. No.: 12/187,183

(22) Filed: Aug. 6, 2008

(51) Int. Cl. H01L 23/52; H01L 21/00; H05K 7/00

(52) U.S. Cl. 257/686; 257/723; 438/109; 257/784; 257/E23.141; 257/E21.001; 361/679.32

(57) ABSTRACT

Memory modules, computing systems, and methods of manufacturing memory modules are disclosed. In one embodiment, a memory module includes a substrate having a first side and a second side opposed to the first side. A plurality of pins is disposed on the first side of the substrate. A first plurality of memory chips are arranged in a first chip layer, the first chip layer overlying the second side of the substrate. Electrical contacts of the first plurality of memory chips are electrically coupled to the pins. A second plurality of memory chips is arranged in a second chip layer, the second chip layer overlying the first chip layer. Electrical contacts of the second plurality of memory chips are electrically coupled to the pins.

### TECHNICAL FIELD

This invention relates generally to electronic systems and methods, and, in particular embodiments, to a stacked ultra high performance memory module.

### BACKGROUND

Memory devices are used in many applications, such as computers, calculators, and cellular phones, as examples. Packaging of memory devices varies in different applications. For many years, single in-line memory modules (SIMMs) were used in computers. However, beginning with memory used for more recent 64-bit processors, dual in-line memory modules (DIMMs) have become more common. DIMMs have separate electrical contacts on each side of the module, while the contacts on SIMMs on both sides are redundant.

FIG. 1 illustrates a known DIMM 102. The DIMM 102 includes a number of dynamic random access memory (DRAM) chips 104 attached to a circuit board 105. Contacts 106 are disposed on one edge of the circuit board 105, and the circuit board 105 includes wiring to connect the DRAM chips 104 to the contacts 106. The DIMM 102 can be connected in a socket of a circuit board, e.g., a motherboard.

FIG. 2 shows a side view of two DIMMs 102 attached to a motherboard 114. DRAM chips 104 are attached to both sides of a substrate 105 using an adhesive 112. In the illustrated embodiment, wire bonds 110 connect the DRAM chips 104 to bond pads on the circuit board 105. In other known modules, DRAM chips 104 can be soldered to the circuit board 105 via solder balls on the lower surface of each DRAM chip 104. The DIMMs 102 include a protective cover 108 over the DRAM chips 104 and wire bonds 110. As illustrated in FIG. 2, DIMMs 102 can be connected to motherboard 114 using a memory slot connector 116 where the DIMM rests on its edge.

Another known connection for a memory module 102 to a motherboard 114 is shown in a cross-sectional view in FIG. 3. In this case, DRAM chips 104 are only shown on one side of the module 102. Attachment of the module 102 to the motherboard 114 can be realized by attachment mechanism 118, which include mechanical devices 118a, 118b, and 118c. Device 118a comprises a hinged connector that the DIMM 102 is inserted or slid into. Device 118c is a retaining clip that the DIMM 102 snaps into, and device 118b is a spring that provides pressure to position the DIMM 102 in the desired position against the retaining clip 118c.

The memory slot connectors 116 and 118 provide added flexibility because each system can include one or more slots that can be populated and upgraded as needed. However, this flexibility comes at a cost. Memory slot connectors 116 and 118 can cause signal integrity problems, due to the parasitic impedance of the connections.

Alternatively, memory chips 104 can be directly mounted on the motherboard. This solution can provide better signal integrity than memory slot connectors 116 or 118 but is inflexible since the memory is not easily replaceable. Many computer users are not capable of desoldering and soldering memory chips to upgrade computers.

FIG. 4 shows a top view of a known motherboard 114 of a computing system including two memory slot connectors 116 and including a central processing unit (CPU) 122 mounted on the motherboard 114 using a socket 124, shown in perspective view in FIG. 5. The CPU 122 is electrically coupled to a memory controller 128 by a front side bus 126. The memory controller 128 is electrically coupled to the memory slot connectors 116 by a memory channel 130. The front side bus 126 and the memory channel 130 comprise metal wiring on the motherboard 114.

The CPU 122 is coupled to the motherboard 114 using the CPU socket 124. The CPU socket 124 provides a high performance connection for the CPU 122 to the motherboard 114, e.g., having a higher performance than the memory slot connectors 116. The memory slot connectors 116 slow down and limit the speed of the motherboard 114 of the computing system.

### SUMMARY OF THE INVENTION

Embodiments of the present invention provide technical advantages by providing novel memory modules and computing systems, and methods of manufacture thereof. The memory modules comprise stacked ultra high performance memory modules that overcome the signal integrity limitations of state-of-the-art interconnect techniques for memory modules.

In accordance with one embodiment of the present invention, a memory module includes a substrate having a first side and a second side opposed to the first side. A plurality of pins is disposed on the first side of the substrate. A first plurality of memory chips is arranged in a first chip layer, the first chip layer overlying the second side of the substrate. Electrical contacts of the first plurality of memory chips are electrically coupled to the pins. A second plurality of memory chips is arranged in a second chip layer, the second chip layer overlying the first chip layer. Electrical contacts of the second plurality of memory chips are electrically coupled to the pins.

The details of one or more embodiments of the invention are set forth in the accompanying drawings and the description below. Other features, objects, and advantages of the invention will be apparent from the description and drawings, and from the claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a drawing illustrating a top view of a known DIMM;

FIG. 2 illustrates a side view of a known memory slot connector;

FIG. 3 illustrates a cross-sectional view of another known memory slot connector;

FIG. 4 shows a top view of a known computer system motherboard;

FIG. 5 shows a perspective view of a known CPU socket;

FIG. 6 shows a top view of a computing system in accordance with an embodiment of the present invention;

FIG. 7 shows a perspective view of the memory module and memory socket shown in FIG. 6;

FIG. 8 shows a block diagram of a computer system that can be implemented with a memory module of the present invention;

FIG. 9 shows a more detailed perspective view of a portion of the memory module in accordance with one embodiment of the present invention;

FIG. 10 shows a portion of a memory module in accordance with another embodiment of the present invention;

FIG. 11 shows a perspective view of a portion of a memory module in accordance with an embodiment of the present invention;

FIG. 12 shows a top view of one of the chip layers of a memory modules in accordance with an embodiment of the present invention;

FIG. 13 shows a memory module of another embodiment of the present invention; and

FIG. 14 shows a top view of a computing system in accordance with an embodiment of the present invention.

Corresponding numerals and symbols in the different figures generally refer to corresponding parts unless otherwise indicated. The figures are drawn to clearly illustrate the relevant aspects of the preferred embodiments of the present invention and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

Embodiments of the present invention achieve technical advantages by using a socket similar to or the same as a socket for a CPU, advantageously providing a state-of the art high performance interconnect for a memory module, resulting in an optimization of the signal quality for the memory module and increasing the speed.

In one aspect, a module stacking technique is combined with state-of-the-art package and mounting techniques to allow a highly flexible, high performance, high density memory module. Embodiments can overcome the signal integrity limitations of state-of-the-art interconnect techniques for memory modules. As an example, memory modules can use existing high performance interconnect techniques such as those used for CPU (main board) socket. This technique can provide flexibility in memory density by allowing for the addition or replacement of memory modules.

In various embodiments, memory sockets can include a huge pin count, which can be utilized for optimal signal and power routing. This can be useful for memory modules that use high density stacking techniques. These sockets also tend to have a well defined foot print. Electrical routing between the CPU and the memory socket can also be accomplished easily.

The present invention will be described with respect to preferred embodiments in a specific context, namely as memory modules used in computing systems. The invention may also be applied, however, to other applications that require memory modules, for example.

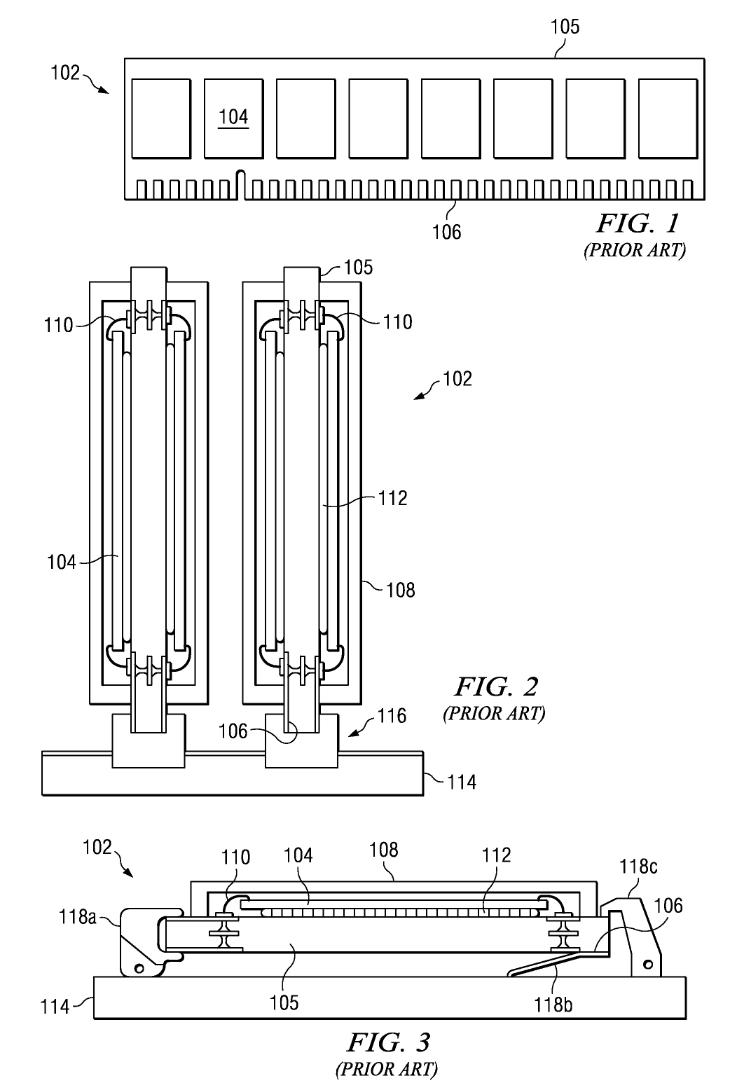

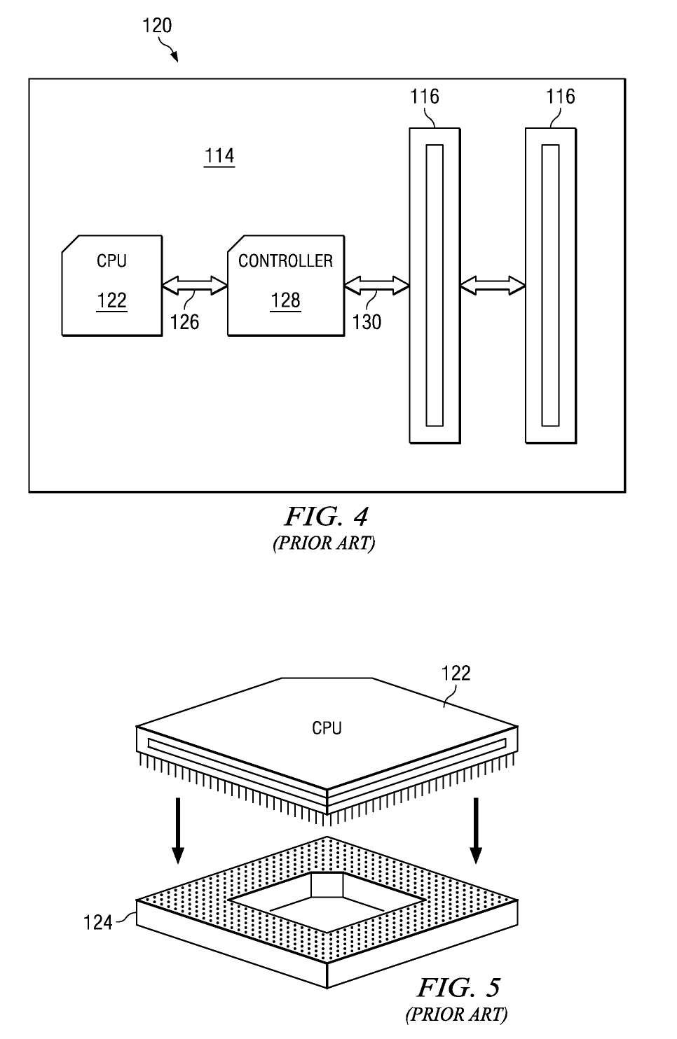

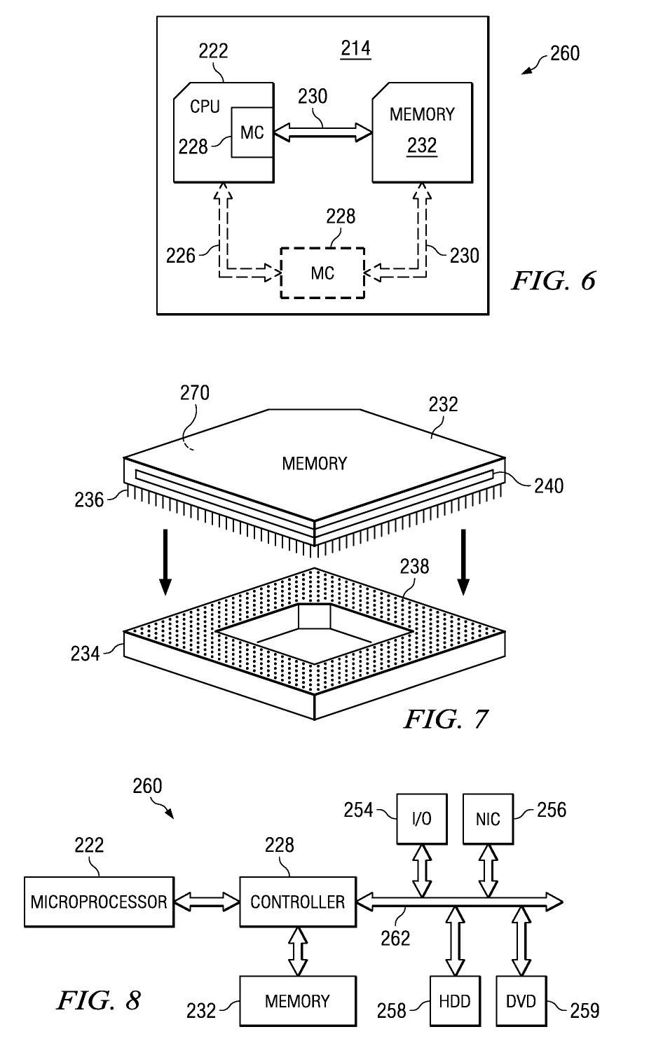

FIG. 6 shows a top view of a computing system 260 in accordance with an embodiment of the present invention. Like numerals are used for the various elements that were used to describe FIGS. 1 through 5, where appropriate. The simplified system of FIG. 6 includes a processor 222 and a memory module 232 that are mounted to a circuit board 214 using a processor socket 124 (see FIG. 5) and a memory socket 234 (see FIG. 7). A memory controller 228 can be integrated into the processor or provided as a separate chip as shown in phantom in the drawing.

The computing system 260 includes a circuit board 214, commonly referred to as a motherboard. The processor socket 124 and the memory socket 234 are mounted on the circuit board 214. In a preferred embodiment, the memory module 232 is a stacked ultra high performance memory module, as will be discussed in more detail below. In an embodiment, the memory module 232 is connected to the memory socket 234 in the same manner that the processor 222 is connected to the processor socket 124. The memory module 232 is functionally coupled to the processor 222 via the circuit board 214, e.g., by metal or conductive lines and wiring formed in or on the circuit board 214. As shown in the figure, the memory 232 can be functionally coupled to the processor via a memory controller 228, which can either be integrated in the processor 222 or as a separate chip, which is shown in phantom. Other components on the motherboard are not shown.

A block diagram of the computing system 260 is shown in FIG. 8. The computer system 260 includes the microprocessor 222, which is coupled to the controller 228. In this example, controller 228 serves the combined purpose of serving as a memory controller and also as a bus interface controller or bridge (e.g., north bridge). In other systems, separate devices could be used for these tasks.

The bus 262 is coupled to a number of components and communicates with the microprocessor 222 via the controller 228. Four examples of components that can be coupled to the bus 262 are shown, i.e., user input/output 254 (which could include a display, mouse, keyboard, microphone or other), network interface card 256, hard disk drive 258 and DVD drive 259. These examples are provided only to show the types of devices that can be utilized in a computer system 260. Other busses or components could be used.

The processor 222 may comprise a microprocessor and may comprise the CPU of the computing system 260, for example. The memory module 232 may comprise a DRAM memory module or other types of memory. For example, the memory module 232 can be a non-volatile memory or a static memory.

FIG. 7 shows a perspective view of the memory module 232 and socket 234. In a computer system, the memory module 232 comprises the working memory for the microprocessor. Accordingly, program and data will be stored. For example, a memory module may include 2 or 4 or 8 Gbytes of dynamic random access memory. As will be discussed below, this memory is provided by a number of memory chips 204, which are arranged in layers stacked in the module 232.

The memory socket 234 is formed from an insulating material such as plastic or other dielectric material, with a number of openings 238 in the insulating material and electrical connections (not visible in the figure) within the openings. The openings 238 and connections are adapted to receive and retain pins 236 on the memory module 232. In this example, the pins are arranged in rows around the perimeter of the memory module 232. Each module pin 236 is electrically connected to the system via an associated opening 238 in the socket 234. The memory socket 234 comprises a high reliability, high performance connection device having high conductivity of the hardware of individual sockets within the openings 238.

The socket 234 may comprise a substantially rectangular or square shape that conforms to the footprint of the memory module, for example. In one example, the socket has dimensions of about 15 mm by 15 mm. As such, two sockets would not require much more surface area than two corresponding memory slots in a conventional system. The memory would, however, have a much lower profile since the module is mounted by the bottom side rather than an edge. Much of this space is saved by encapsulating bare die in the module.

In another example, a 30 mm×30 mm socket could have as many as eight 1 G DDR2 DRAM's per layer based on a chip size (silicon) of 12 mm×7 mm, which is an average size for this type of DRAM. In order to be compatible with an average DIMM when comparing the number of attached DRAM's there would be a need for a minimum of two layers since the average number of DRAM's per DIMM is typically between 16 and 32. Of course, one could also go down to a 15 mm×15 mm socket size for a four DRAM per layer module with four layers. In general, a module could include any number of DRAMs per layer.

The interface between the memory module 232 and the memory socket 234 may be based on a pin grid array (PGA) architecture. For example, short, stiff pins 236 on the underside of the module 232 mate with the holes or openings 238 in the socket 234. The hardware in the openings 238 may comprise zero insertion force (ZIF) sockets that allow the pins 236 to be inserted with little resistance, and then a lever (not shown) on the socket 234 is flipped, causing the pins 236 to be gripped firmly and provide a reliable contact. Alternatively, other types of sockets may be used for the socket 234.

The memory socket 234 may comprise the same type of connections, e.g., may comprise the same type of hardware inside the openings 238 as the hardware inside the openings of the processor socket (labeled 124 in FIG. 5) for the processor 222. The memory socket 234 and processor socket may have the same or different footprint or shape. For example, the memory module, which contains a number of chips, may have a larger footprint. If the memory socket 234 is the same size and has the same pin configuration as the processor socket 124, however, a manufacturing advantage can be achieved because the number of different types of components required is reduced.

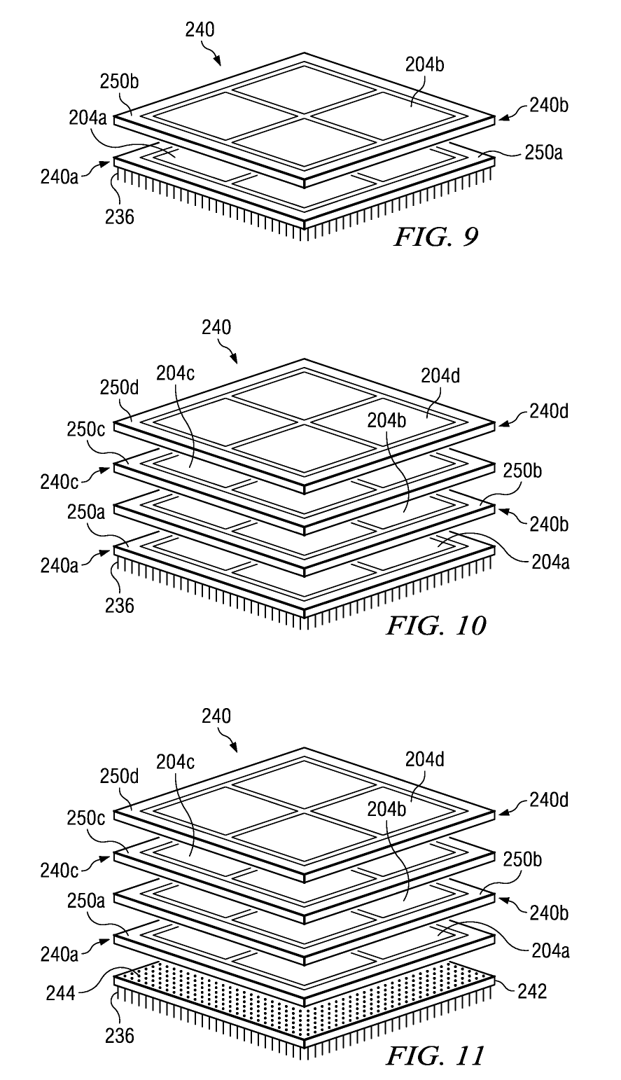

The number of openings 238 of the memory socket 234 may be the same as or greater than the number of pins 236 on the memory module 232. As an example, a module socket may include one hundred or more pins, e.g., over two hundred in some embodiments. For example, a known 240-pin DIMM can be used for DDR2 SDRAM, DDR3 SDRAM and FB-DIMM DRAM. The module of the present invention can include at least this number of contacts and potentially more. For example, a Socket 7 compliant socket, which can be used with various microprocessors, has 321 contacts. Additional contacts could allow for more functionality, as well as more power/ground connections, in the memory. In embodiments wherein the number of openings 238 of the memory socket 234 is greater than the number of connections needed by the module 232, some of the pins 236 of the memory module 232 may comprise dummy pins (e.g., grounded pins) or some of the openings will not have a corresponding pin inserted therein or the openings which are not needed for a single memory module, as shown in FIG. 7, could be defined for addressing further stacked memory modules, as shown in FIG. 10, in order to increase the total system memory. Stacking of the memory modules will not increase the footprint size.

FIG. 9 shows a perspective view of a portion of the memory module 232 without encapsulation. The memory portion of the memory module 232 shown in FIG. 9 includes a number of stacked chip layers 240, each of which includes a number of memory chips 204. In the embodiment of FIG. 9, the memory includes two chip layers 240a and 240b, each chip layer 240 including four chips. In other embodiments, additional chip layers can be included and/or more chips can be included in each layer as discussed above.

The memory module 232 includes a substrate 250a. The pins 236 are disposed on the bottom side of the substrate 250a. In the illustrated embodiment, the pins 236 may be arranged in rows around a periphery of the bottom side of the substrate 250a. The pins can be in other configurations as well, e.g., in an array over the entire bottom surface.

Memory chips 204a are arranged in a first chip layer 240a that overlies the top side of the substrate 250a. The chips 204 can attached to the substrate 250a using an adhesive, as an example. Electrical contacts of the memory chips 204a are electrically coupled to the pins 236, e.g., by wire bonds and metal lines (not shown) on the substrate 250a. Alternatively, the memory chips 204a can include through silicon vias for electrically coupling to the substrate 250a. As another example, the memory chips 204 can be formed with a redistribution layer and include contacts, e.g., compliant bumps, so that the chip is mounted face down and connected to the substrate via the bumps.

A second group of memory chips 204b is arranged in a second chip layer 240b that overlies the first chip layer 240a. Electrical contacts of the second group of memory chips 204b are also electrically coupled to the pins 236. The second plurality of memory chips 204b can be mounted on a substrate 250b and electrically coupled to the substrate 250b using wire bonds or through silicon/substrate vias (as described below). The substrate 250b may include bond pads on a back surface thereof that are coupled to bond pads on the first plurality of memory chips 204a of the first chip layer 240a. In other words, the substrate 250b may be an intermediate substrate disposed between the first chip layer 240a and the memory chips 204b of the second chip layer 240b.

Alternatively, the electrical contacts of the second plurality of memory chips 204b may be electrically coupled to the electrical contacts of the first plurality of memory chips 204a, which are electrically coupled to the pins 236. In this example, the memory chips 204 may use through silicon vias, e.g., an electrical connector that extends through the substrate of the chip. As another alternative, the second layer of chips can be connected via compliant bumps as described above.

The memory chips 204 are preferably DRAM chips, although alternatively, other types of memory devices could also utilize concepts of the present invention. The DRAM chips may comprise synchronous DRAM chips, each DRAM chip including at least 256 million memory cells, as one example. For example, 1 Gbit or 2 Gbit DDR SDRAM chips can be included in the memory module 232. In the illustrated example, a 64-bit data bus can be achieved by including eight x8 chips arranged in two layers in one embodiment. In another embodiment, more than one rank can be included in a module so that some of the data pins for different memory chips are connected in parallel. This embodiment can be especially useful in embodiments with more than two layers or more than four chips per layer.

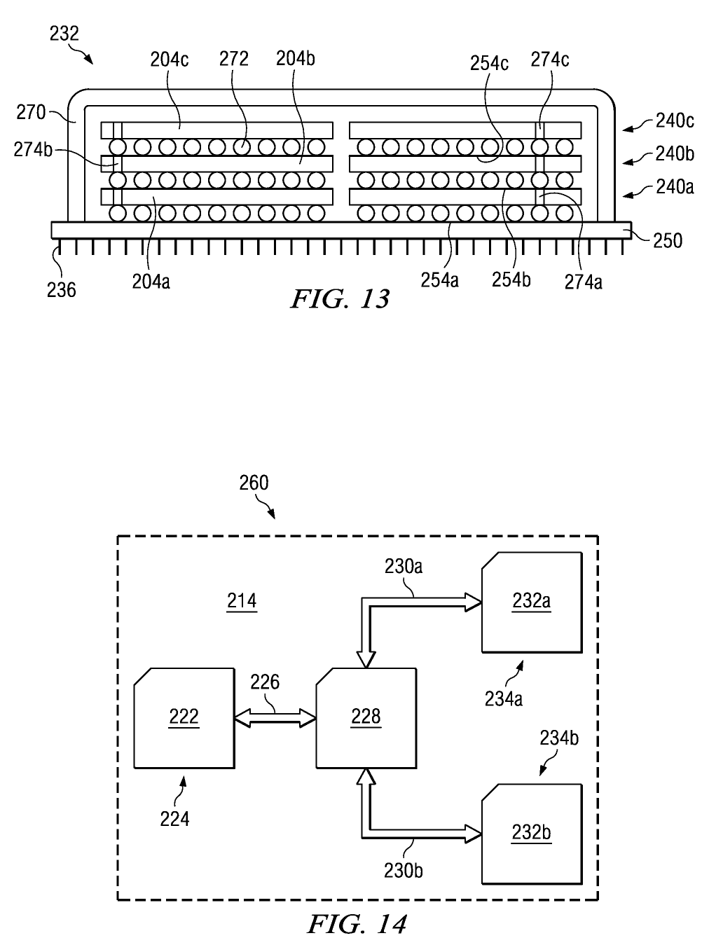

FIG. 10 has been included to show that the module 232 can include more than two chip layers as discussed above. In this example, the memory module 232 includes four chip layers 240a, 240b, 240c, and 240d (and the embodiment shown in FIG. 13 the memory module 232 includes three chip layers 240a, 240b, and 240c). The memory module 232 may also include five or more chip layers. In the embodiment of FIG. 10, the memory module 232 includes four stacked chip layers 240a-d that each includes four memory chips 204a-204d, for a total of 16 chips.

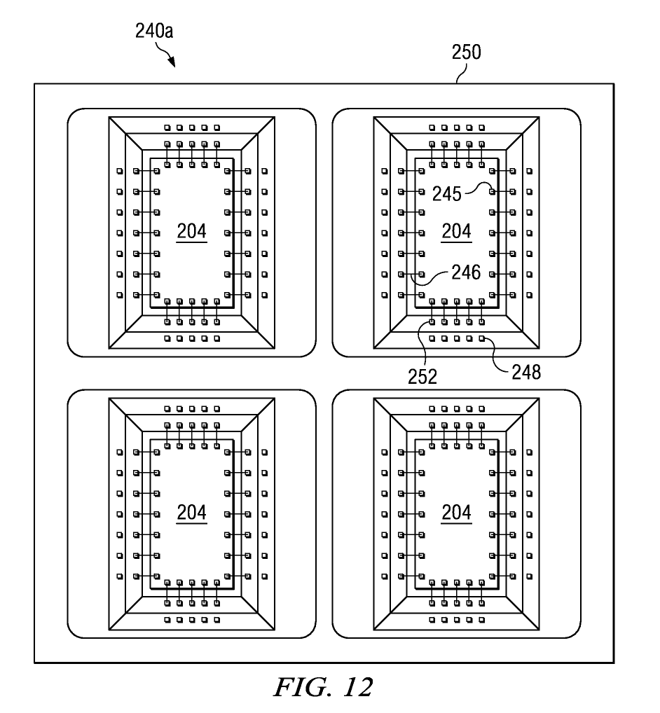

Electrical contacts of the first plurality of memory chips 204a of the first chip layer 240a may be electrically connected to electrical contacts of the substrate 250a via first wire bonds (not shown in FIG. 9; see wire bonds 246 of FIG. 12). Electrical contacts of the second plurality of memory chips 204b of the second chip layer 240b may be electrically connected to electrical contacts of the intermediate substrate 250b via second wire bonds (also not shown in FIG. 9). In some embodiments, the intermediate substrate 250b may include through vias (also not shown) that are electrically connected to the electrical contacts of the intermediate substrate 250b, at least some of the through vias being electrically connected to electrical contacts of the substrate 250a.

FIG. 11 shows a perspective view of a portion 240 of memory module 232 in accordance with another embodiment of the present invention. In this embodiment, each of the memory layers can be the same. The lowest layer 240a is attached to a substrate 242 that includes the pins 236 that connect to the memory socket. In this case, the memory chips 204 of each layer are mounted on an associated substrate 250. The chip layers 240 are identical boards, which can provide a manufacturing and inventory control advantage.

FIG. 12 shows a top view of one of the chip layers 240a of the memory modules 232 shown in FIGS. 9 through 11. Electrical contacts 245 of the memory chips 204 are electrically connected to electrical contacts 252 of the substrate 250 via wire bonds 246. The substrate 250 also includes through vias 248 that are electrically connected to electrical contacts of an adjacent substrate 250 or substrate 242 shown in FIG. 11. The through vias 248 may extend through to and may be present on both the top and bottom sides of the substrate 250. At least some of the through vias 248 are electrically connected to electrical contacts of the substrate by connections not shown.

The through vias 248 provide electrical connections between the chip layers 240. For example, the through vias 248 of the substrates 250a, 250b, 250c, and 250d may be connected together using solder bonds or a conductive adhesive. For example, the data bus, as well as some of the address and control lines, can be coupled to multiple chips. Other control lines such as clock enable (CKE), chip select (CS), on die termination control (ODT) and, possibly a portion of the address bus, could be connected individually to only some of the chips. In one embodiment, each layer 240 of the module can form one rank of memory.

FIG. 13 shows another embodiment of the present invention, where each memory chip 204 of the memory module 232 is bonded directly to a chip in an adjacent chip layer 240. In one embodiment, the memory chips 204 are electrically connected via through silicon vias 274 disposed on the memory chips. The substrate 250 includes the external contact pins 236. The lower memory chips 204a may can be coupled to the substrate 250 using silicon vias 474a, as shown. Two adjacent memory chips 204 (or the lowest memory chips 204 and the substrate 240) may be bonded together at the bond pads 254 using solder or a conductive adhesive 272, for example.

Only three chip layers 240 are shown in FIG. 13. Alternatively, a memory module 232 can include other configurations as discussed above.

FIG. 14 shows a top view of a motherboard 214 of a computing system 260 in accordance with an embodiment of the present invention. In this example, the motherboard 214 includes two sockets 234a and 234b for memory modules 232a and 232b. In an upgradeable system, all sockets 234 do not need to be filled with memory for the system to operate. Each memory module 232 can be connected to a corresponding memory socket 234 in the same manner that the processor 222 is coupled to the processor socket 224. Additional memory sockets 234, e.g., third memory sockets, fourth memory sockets, etc., and/or additional memory modules 232 may also be included on the circuit board 214 to provide a larger amount of memory or providing an expandable memory card for a computing device.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1 A memory module comprising:
a substrate having a first side and a second side opposed to the first side;
a plurality of pins disposed on the first side of the substrate;
a first plurality of memory chips arranged in a first chip layer, the first chip layer overlying the second side of the substrate, electrical contacts of the first plurality of memory chips being electrically coupled to the pins; and
a second plurality of memory chips arranged in a second chip layer, the second chip layer overlying the first chip layer, electrical contacts of the second plurality of memory chips being electrically coupled to the pins.

2. The memory module of claim 1, wherein the first plurality of memory chips are mounted on the substrate.

3. The memory module of claim 2, further comprising an intermediate substrate, the second plurality of memory chips being mounted on the intermediate substrate.

4. The memory module of claim 3, wherein the electrical contacts of the first plurality of memory chips are electrically connected to electrical contacts of the substrate via first wire bonds and wherein the electrical contacts of the second plurality of memory chips are electrically connected to electrical contacts of the intermediate substrate via second wire bonds.

5. The memory module of claim 4, wherein the intermediate substrate includes through vias electrically connected to the electrical contacts of the intermediate substrate, at least some of the through vias being electrically connected to the electrical contacts of the substrate.

6. The memory module of claim 1, wherein the second plurality of memory chips and the first plurality of memory chips are electrically connected to one another via through silicon vias.

7. The memory module of claim 1, wherein the first plurality of memory chips includes four memory chips arranged in a two by two matrix and wherein the second plurality of memory chips includes four memory chips arranged in a two by two matrix.

8. The memory module of claim 1, wherein the first plurality of memory chips and the second plurality of memory chips each include a plurality of dynamic random access memory (DRAM) chips.

9. The memory module of claim 8, wherein the DRAM chips comprises synchronous DRAM chips, each DRAM chip including at least 256 million memory cells.

10. The memory module of claim 1, further comprising a third plurality of memory chips arranged in a third chip layer, the third chip layer overlying the second chip layer, electrical contacts of the third plurality of memory chips being electrically coupled to the pins.

11. The memory module of claim 10, further comprising a fourth plurality of memory chips arranged in a fourth chip layer, the fourth chip layer overlying the third chip layer, electrical contacts of the fourth plurality of memory chips being electrically coupled to the pins.

12. The memory module of claim 1, wherein the pins are arranged in rows around a periphery of the first side of the substrate.

13. A computing system comprising:
a circuit board;
a processor socket mounted on the circuit board;
a memory socket mounted on the circuit board;
a processor physically and electrically connected to the processor socket;
a memory module physically and electrically connected to the memory socket in the same manner that the processor is connected to the processor socket, the memory module being functionally coupled to the processor via the circuit board.

14. The system of claim 13, further comprising a controller mounted on the circuit board, the memory module being functionally coupled to the processor through the controller.

15. The system of claim 14, wherein the controller and the processor are integrated in a single integrated circuit chip.

16. The system of claim 14, further comprising a peripheral bus coupled to the processor via the controller.

17. The system of claim 13, wherein:
the processor includes a plurality of pins, each processor pin being connected to an associated opening in the processor socket; and
the memory module includes a plurality of pins, each memory module pin being connected to an associated opening in the memory socket.

18. The system of claim 13, wherein the processor comprises a microprocessor and wherein the memory module comprises a dynamic random access memory (DRAM) memory module.

19. The system of claim 13, wherein the memory socket is the same size as the processor socket.

20. The system of claim 13, further comprising a second memory socket mounted on the circuit board.

21. The system of claim 20, further comprising a second memory module connected to the second memory socket in the same manner that the processor is connected to the processor socket, the second memory module being functionally coupled to the processor via the circuit board.

22. The system of claim 13, wherein the memory socket comprises a zero insertion force socket.

23. The system of claim 13, wherein the memory module comprises:
a substrate having a first side and a second side opposed to the first side;
a plurality of pins disposed on the first side of the substrate, each pin being connected to an associated opening in the memory socket;
a first plurality of memory chips arranged in a first chip layer, the first chip layer overlying the second side of the substrate, electrical contacts of the first plurality of memory chips being electrically coupled to the pins; and
a second plurality of memory chips arranged in a second chip layer, the second chip layer overlying the first chip layer, electrical contacts of the second plurality of memory chips being electrically coupled to the pins.

24. A method of manufacturing a memory module, the method comprising:
providing a substrate, the substrate having a first side and a second side opposed to the first side;
attaching a plurality of pins to the first side of the substrate;
overlying a first plurality of memory chips over the second side of the substrate, the first plurality of memory chips being arranged in a first chip layer and having electrical contacts;
electrically coupling the electrical contacts of the first plurality of memory chips to the pins on the substrate;
overlying a second plurality of memory chips over the first chip layer, the second plurality of memory chips being arranged in a second chip layer and having electrical contacts; and
electrically coupling the electrical contacts of the second plurality of memory chips to the pins on the substrate.
